(19) United States
(12) Patent Application Publication
(10) Pub. No.: US 2016/0266870 A1
(43) Pub. Date: Sep. 15, 2016

(54) Sound Effect Adjusting Method and Apparatus

(71) Applicant: Tencent Technology (Shenzhen) Company Limited, Shenzhen (CN)

(72) Inventors: Xiayu Wu, Shenzhen (CN); Rong Wan, Shenzhen (CN)

(73) Assignee: Tencent Technology (Shenzhen) Company Limited, Shenzhen (CN)

(21) Appl. No.: 15/165,284

(22) Filed: May 26, 2016

Related U.S. Application Data
(63) Continuation of application No. PCT/CN2015/073655, filed on Mar. 4, 2015.

(30) Foreign Application Priority Data
Mar. 11, 2014 (CN) 201410088091.9

(51) Int. Cl. G06F 3/16; H03G 7/00

(52) U.S. Cl. CPC G06F 3/165; H03G 7/002

(57) ABSTRACT

A sound effect adjusting method and apparatus are provided. The method includes: determining an initial sound effect intensity value corresponding to each object currently selected; determining, according to the initial sound effect intensity value corresponding to each object currently selected, a sound effect intensity value corresponding to each type of object currently selected; acquiring a state of each type of object currently selected; adjusting, according to the state of each type of object currently selected, the sound effect intensity value corresponding to each type of object; and combining, according to adjusted sound effect intensity values of all types of objects currently selected, sound effects corresponding to all the types of objects, and using the combined sound effects as a sound effect adjustment result.

### CROSS REFERENCE TO RELATED APPLICATION

This application is a continuation of International Application No. PCT/CN2015/073655, filed on Mar. 4, 2015, which claims priority to Chinese patent application No. 201410088091.9, filed on Mar. 11, 2014, the content of which are incorporated herein by reference in their entirety.

### FIELD OF THE INVENTION

The present disclosure relates to the field of computer technologies, and in particular, to a sound effect adjusting method and apparatus.

### BACKGROUND OF THE INVENTION

The development of computer technologies is accompanied with more and more types of application programs. Poor user experience of an application program leads to a decrease in the number of users. The number of users is an important index for evaluating an application program, and a sound effect of the application program is important reference for measuring user experience. Therefore, how to adjust the sound effect has become a key to increasing the number of users of the application program.

In a related technology, during sound effect adjustment, currently selected objects in an application program are determined, and further, a sound effect corresponding to each object currently selected is determined; then, sound effects of all currently selected objects in the application program are mixed, to obtain a mixed sound effect of all the currently selected objects in the application program; after that, a mixed sound effect of all objects selected last time in the application program is adjusted to be the mixed sound effect of all the objects currently selected in the application program, thereby implementing the adjustment of the sound effect. In addition, in a case in which types the currently selected objects are the same as those of the objects selected last time, the related technology plays the adjusted sound effect; in a case in which types the currently selected objects are different from those of the objects selected last time, the related technology uses the foregoing adjustment process to adjust the sound effect, and plays an adjusted sound effect. By using an example in which the application program is a martial arts role playing game among online games, and objects are equipment in the martial arts game, if objects selected last time in the application program are a cloth gown and a half sword, a sound effect played last time is a mixed sound effect of the cloth gown and half sword, and if objects currently selected in the application program are armor and a hacking knife, the mixed sound effect of the cloth gown and half sword needs to be adjusted to be a mixed sound effect of the armor and hacking knife at this time, thereby playing the mixed sound effect of the armor and hacking knife.

However, in the related technology, during sound effect adjustment, the sound effect is adjusted only when the type of a selected object in the application program changes, and the sound effect is not adjusted when the state of a selected object in the application program changes as a user uses the selected object; consequently, the sound effect adjusted by using the related technology lacks timeliness.

### SUMMARY OF THE INVENTION

Accordingly, embodiments of the present invention provide a sound effect adjusting method and apparatus. The technology solution is as follows:

According to one aspect, a sound effect adjusting method is provided, the method including:
determining an initial sound effect intensity value corresponding to each object currently selected;
determining, according to the initial sound effect intensity value corresponding to each object currently selected, a sound effect intensity value corresponding to each type of object currently selected, each type of object including at least one object;
acquiring a state of each type of object currently selected, different states corresponding to different sound effect intensity values;
adjusting, according to the state of each type of object currently selected, the sound effect intensity value corresponding to each type of object, to obtain an adjusted sound effect intensity value corresponding to each type of object; and
combining, according to sound effect intensity values of all types of objects currently selected, sound effects corresponding to all the types of objects, and using the combined sound effects as a sound effect adjustment result.

According to another aspect, a sound effect adjusting apparatus is provided, the apparatus including:
a first determining module, configured to determine an initial sound effect intensity value corresponding to each object currently selected;
a second determining module, configured to determine, according to the initial sound effect intensity value corresponding to each object currently selected, a sound effect intensity value corresponding to each type of object currently selected, each type of object including at least one object;
an acquiring module, configured to acquire a state of each type of object currently selected, different states corresponding to different sound effect intensity values;
an adjustment module, configured to adjust, according to the state of each type of object currently selected, the sound effect intensity value corresponding to each type of object, to obtain an adjusted sound effect intensity value corresponding to each type of object; and
a combining module, configured to combine, according to sound effect intensity values of all types of objects currently selected, sound effects corresponding to all the types of objects, and use the combined sound effects as a sound effect adjustment result.

According to an initial sound effect intensity value corresponding to each object currently selected, a sound effect intensity value corresponding to each type of object currently selected is determined, and further, the sound effect intensity value corresponding to each type of object is adjusted according to a state of each type of object currently selected, and sound effects corresponding to all types of objects are combined according to adjusted sound effect intensity values corresponding to all the types of objects currently selected, so that the combined sound effects can reflect a change in states of the currently selected objects; therefore, the adjusted sound effect is time sensitive.

### DESCRIPTION OF THE DRAWINGS

To illustrate the technical solutions in the embodiments of the present invention more clearly, the following briefly introduces the accompanying drawings required for describing the embodiments of the present invention. Apparently, the accompanying drawings in the following description show merely some embodiments of the present invention, and a person of ordinary skill in the art may still derive other drawings from these accompanying drawings without creative efforts.

FIG. 1 is a flowchart of a sound effect adjusting method according to an embodiment of the present invention;

FIG. 2 is a flowchart of a sound effect adjusting method according to an embodiment of the present invention;

FIG. 3 is a schematic structural diagram of a sound effect adjusting apparatus according to an embodiment of the present invention;

FIG. 4 is a schematic structural diagram of an adjustment module according to an embodiment of the present invention;

FIG. 5 is a schematic structural diagram of a combining module according to an embodiment of the present invention; and

FIG. 6 is a schematic structural diagram of a terminal according to an embodiment of the present invention.

### DETAILED DESCRIPTION OF THE PREFERRED EMBODIMENTS

To make the objectives, the technical solutions, and advantages of the present disclosure clearer, the implementation manners of the present disclosure will be described in more detail below with reference to the accompanying drawings.

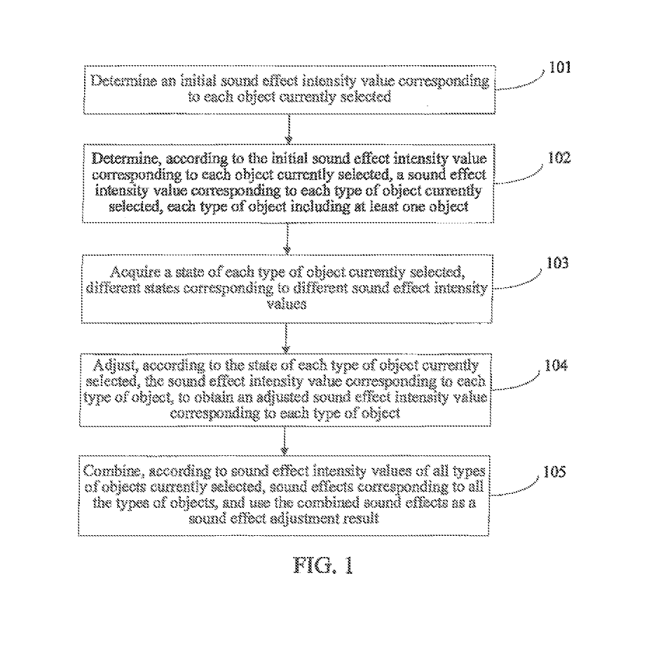

This embodiment of the present invention provides a sound effect adjusting method. Referring to FIG. 1, a process of the method provided by this embodiment includes:

101: Determine an initial sound effect intensity value corresponding to each object currently selected.
102: Determine, according to the initial sound effect intensity value corresponding to each object currently selected, a sound effect intensity value corresponding to each type of object currently selected, each type of object including at least one object.
103: Acquire a state of each type of object currently selected, different states corresponding to different sound effect intensity values.
104: Adjust, according to the state of each type of object currently selected, the sound effect intensity value corresponding to each type of object, to obtain an adjusted sound effect intensity value corresponding to each type of object.
105: Combine, according to sound effect intensity values of all types of objects currently selected, sound effects corresponding to all the types of objects, and use the combined sound effects as a sound effect adjustment result.

In this embodiment of the present invention, the state of each type of object currently selected includes: a remaining quantity and a remaining total weight corresponding to each type of object currently selected.

The acquiring the state of each type of object currently selected includes:
acquiring the remaining quantity and the remaining total weight corresponding to each type of object currently selected.

The adjusting, according to the state of each type of object currently selected, the sound effect intensity value corresponding to each type of object includes:
comparing the remaining quantity corresponding to each type of object currently selected with an initial quantity corresponding to each type of object currently selected, and comparing the remaining total weight corresponding to each type of object currently selected with an initial total weight corresponding to each type of object currently selected; and
adjusting the sound effect intensity value corresponding to each type of object according to a comparison result.

Specifically, the sound effect intensity value corresponding to each type of object currently selected is lowered if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

In this method, the combining, according to sound effect intensity values of all types of objects currently selected, sound effects corresponding to all the types of objects includes:
detecting a current implementation environment, and determining, according to the current implementation environment, combination ratios for combining the sound effects corresponding to all the types of objects; and
combining the sound effects corresponding to all the types of objects according to the determined combination ratios and the adjusted sound effect intensity values corresponding to all the types of objects currently selected.

The method provided by this embodiment of the present invention can combine sound effects corresponding to all types of objects according to adjusted sound effect intensity values corresponding to all the types of objects currently selected, so that the combined sound effects can reflect a change in states of the currently selected objects, and therefore, the adjusted sound effect is time sensitive.

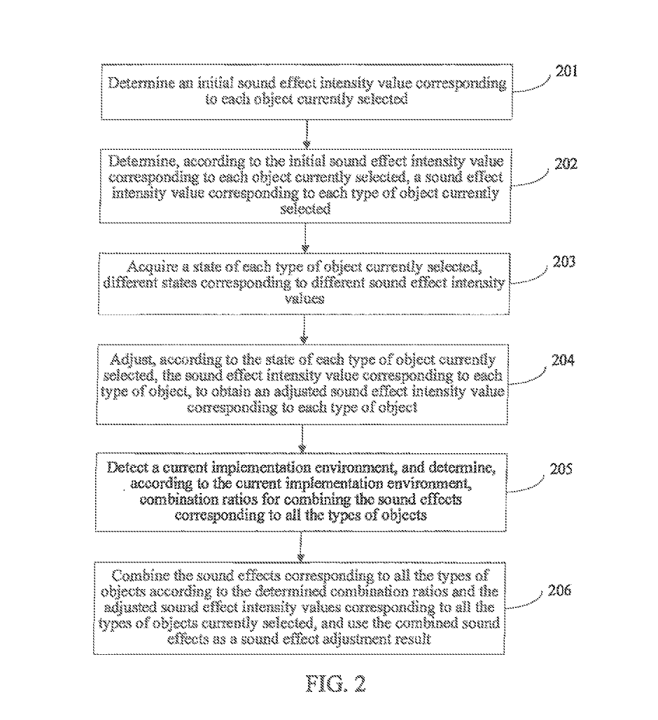

The development of computer technologies is accompanied with an increase in types and quantity of application programs. In an existing sound effect adjusting method, the sound effect is adjusted only when types of objects selected by a user change, and is not adjusted when states of selected objects change; however, the user wants the sound effect played in the application program to be time sensitive when using the application program, so that a change in current states of the selected objects can be reflected in real time. In order to satisfy the requirement of the user, this embodiment of the present invention provides a sound effect adjusting method. For ease of description, the sound effect adjusting method provided in this embodiment of the present invention is described in detail with reference to the content of the foregoing embodiment. Referring to FIG. 2, a process of the method provided by this embodiment includes:

201: Determine an initial sound effect intensity value corresponding to each object currently selected.

A sound effect intensity value is a degree of complexity presented when a sound effect is played, where a small sound effect intensity value indicates a slight sound generated by collision and friction, and a large sound effect intensity value indicates a loud sound generated by collision and friction; the sound effect intensity value mainly depends on a quantity and weight of objects in the application program. For example, if the application program has a large quantity of objects and the objects are heavy, the sound effect played in the application program has a large intensity value; if application program has a small quantity of objects and the objects are light weighted, the sound effect played in the application program sound effect has a small intensity value.

Objects are important components of an application program, and each application program includes multiple objects. In order to make the application program more attractive so that different sound effects can be played according to objects selected by a user when the user uses the application program, each object in the application program corresponds to an initial sound effect intensity value. The initial sound effect intensity value is a sound effect intensity value of each object at the beginning, namely, a sound effect intensity value of each object when the user starts using the application program.

Further, the initial intensity value corresponding to each object in the application program is a basis for sound effect adjustment in subsequent steps, and each object in the application program corresponds to a different initial intensity value. Therefore, before adjusting the sound effect, the method provided by this embodiment first needs to determine each object currently selected, thereby determining, according to each object currently selected, the initial sound effect intensity value corresponding to each object currently selected.

The method of determining each object currently selected includes, but is not limited to, providing an object selecting page in the application program so that the user selects, on the object selecting page, objects that need to be used during use of the application program, then detecting the selection operation of the user on the object selecting page to obtain the objects that are selected by the user on the object selecting page, and determining each object currently selected.

Specifically, the manner of determining an initial sound effect intensity value corresponding to each object currently selected includes, but is not limited to, the following process:

First step: Determine, according to samples classified in advance, a sample to which each object currently selected belongs.

The sample is a set of all objects having a same attribute in the application program, where each sample at least includes one object. The samples classified in advance are an important basis for determining the sample to which each object currently selected belongs. Therefore, in order to determine, according to the samples classified in advance, the sample to which each object currently selected belongs, the method provided by this embodiment needs to classify all objects in the application program into different samples. Specifically, when all the objects in the application program are classified into different samples, all the objects in the application program may be classified into different samples according to object attributes in the application program.

By using a first-person modern shooting game application as an example, the first-person modern shooting game application includes the following objects: rifle, machine gun, sniper rifle, pistols of different models, half sword, dagger, hacking knife, fire axe, flash grenade, smoke grenade, explosive grenade, C4 explosive, bomb disposal backpack, night vision device, common body armor, body armor with helmet, and the like; all the objects in the application program are classified into the following six samples according to attributes of the objects in the application program: primary weapon: rifle, machine gun, sniper rifle, and the like; secondary weapon: pistols of different models, and the like; melee weapon: half sword, dagger, hacking knife, fire axe, and the like; grenade: flash grenade, smoke grenade, explosive grenade, and the like; tactical equipment backpack: C4 explosive, bomb disposal backpack, night vision device, and the like; and body armor: common body armor, body armor with helmet, and the like.

All the objects in the application program are classified into different samples, and each object in the application program corresponds to one sample; therefore, after each object currently selected is determined, the sample to which each object currently selected belongs may be determined according to a correspondence between each object and the sample.

Second step: Determine, according to the sample to which each object currently selected belongs, an initial sound effect intensity value, in the sample, corresponding to each object currently selected.

Because objects of different attributes present different types of sound effect intensities when being played, in order to distinguish sound effect intensities of different samples, the method provided by this embodiment sets different types of sound effect intensity values for different samples. By using a first-person modern shooting game application as an example, a maximum value of the sound effect intensity value of the primary weapon may be set to a, a maximum value of the sound effect intensity value of the secondary weapon may be set to b, a maximum value of the sound effect intensity value of the melee weapon may be set to c, a maximum value of the sound effect intensity value of the grenade may be set to d, a maximum value of the sound effect intensity value of the tactical backpack may be set to e, and a maximum value of the sound effect intensity value of the body armor may be set to f. Because different objects in a same sample have different sound effect intensities when being played, to distinguish different sound effects of different objects in the sample, after setting different sound effect intensity values for different samples, the method provided by this embodiment further sets a different initial sound effect intensity value for each object in the sample. Specifically, the manner of setting a different initial sound effect intensity value for each object in the sample includes, but is not limited to, setting a different initial sound effect intensity value for each object in the sample according to a weight relationship of objects in the sample. For example, the primary weapon includes objects such as rifle, machine gun, and sniper rifle, and because the weight of the rifle is less than that of the machine gun, and the weight of the machine gun is less than that of the sniper rifle, the sound effect intensity values of the rifle, machine gun, and sniper rifle may be set to 0.3a, 0.5a, and 0.8a.

Further, because each object in the application program corresponds to an initial sound effect intensity value in the sample, an initial sound effect intensity corresponding to each object currently selected in the sample may be determined according to the sample to which each object currently selected belongs.

202: Determine, according to the initial sound effect intensity value corresponding to each object currently selected, a sound effect intensity value corresponding to each type of object currently selected.

Each type of object in the application program includes at least one object; although the initial sound effect intensity value corresponding to each object currently selected has been determined in step 201, when each type of objects currently selected includes more than one object, the sound effect intensity value corresponding to this type of objects is no longer an initial sound effect intensity value corresponding to one object. Therefore, in this step, on the basis of step 201, the sound effect intensity corresponding to each type of object currently selected is determined according to the initial sound effect intensity value corresponding to each object currently selected.

The manner of determining, according to the initial sound effect intensity value corresponding to each object currently selected, a sound effect intensity value corresponding to each type of object currently selected includes, but is not limited to, the following manner:

First, a quantity of each type of object currently selected is determined.

The manner of determining a quantity of each type of object currently selected includes, but is not limited to, detecting a selection operation of a user on an object selecting page, and further determining, according to the detected selection operation of the user on the object selecting page, the quantity of each type of object currently selected.

Secondly, the initial sound effect intensity values corresponding to the determined quantity of objects currently selected are combined according to determined combination ratios, to obtain the sound effect intensity value of each type of object currently selected.

The combination ratio may be 1 or 0.5, and definitely may be other values, and this embodiment does not specifically limit the combination ratio.

For ease of comprehension of the foregoing process, detailed description is provided in the following by using a specific example.

For example, the currently selected objects are three explosive grenades, and if the sound effect intensity value corresponding to the explosive grenade is 0.6d, a combined sound effect intensity value of the three explosive grenades is 1.8d when the set combination ratio is 1.

203: Acquire a state of each type of object currently selected, different states corresponding to different sound effect intensity values.

Different states of each type of object currently selected correspond to different sound effect intensity values, and therefore, to make the sound effect played in the application program more time sensitive and be capable of reflecting a change in current states of the selected objects in real time, the method provided by this embodiment needs to acquire the state of each type of object currently selected. The state of each type of object currently selected includes, but is not limited to, a remaining quantity and a remaining total weight corresponding to each type of object currently selected. The manner of acquiring a state of each type of object currently selected includes, but is not limited to, acquiring the remaining quantity and the remaining total weight corresponding to each type of object currently selected.

The acquiring the remaining quantity and the remaining total weight corresponding to each type of object currently selected includes, but is not limited to, detecting, by using a counting apparatus, the remaining quantity corresponding to each type of object currently selected, and acquiring, by using a weight measuring apparatus, the remaining total weight corresponding to each type of object currently selected. The counting apparatus includes, but is not limited to, a counter, and the weight measuring apparatus includes, but is not limited to, a weight sensing apparatus.

204: Adjust, according to the state of each type of object currently selected, the sound effect intensity value corresponding to each type of object, to obtain an adjusted sound effect intensity value corresponding to each type of object.

Specifically, the adjusting, according to the state of each type of object currently selected, the sound effect intensity value corresponding to each type of object includes, but is not limited to:
comparing the remaining quantity corresponding to each type of object currently selected with an initial quantity corresponding to each type of object currently selected, and comparing the remaining total weight corresponding to each type of object currently selected with an initial total weight corresponding to each type of object currently selected; and
adjusting the sound effect intensity value corresponding to each type of object according to a comparison result.

Specifically, the adjusting the sound effect intensity value corresponding to each type of object according to a comparison result includes, but is not limited to:
lowering the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

The foregoing process of adjusting the sound effect intensity value corresponding to each type of object according to a comparison result may be divided into the following two situations:

First situation: If the remaining quantity corresponding to each type of object currently selected is less than the initial quantity corresponding to each type of object currently selected, and the remaining total weight corresponding to each type of object currently selected is less than the initial total weight corresponding to each type of object currently selected, the sound effect intensity value corresponding to each type of object currently selected is lowered.

In the first situation, as time of using the application program by the user goes by, the quantity corresponding to each type of object currently selected decreases, that is, the remaining quantity corresponding to each type of object currently selected is less than the initial quantity corresponding to each type of object currently selected. Moreover, as the quantity corresponding to each type of object currently selected decreases, the weight corresponding to each type of object currently selected decreases, that is, the remaining total weight corresponding to each type of object currently selected is less than the initial total weight corresponding to each type of object currently selected. When the quantity and total weight of each type of object currently selected decrease, the sound effect intensity value corresponding to each type of object currently selected decreases, and therefore, in this case, the sound effect intensity value corresponding to each type of object currently selected needs to be lowered.

For ease of comprehension of the foregoing process, detailed description is provided in the following by using a specific example.

For example, the currently selected objects are smoke grenades; the initial quantity corresponding to the currently selected smoke grenades is 5, and the initial total weight is 10 kilograms; after a period of time, as the user uses smoke grenades in the application program, the remaining quantity corresponding to the currently selected smoke grenades turns to be 3, and the total weight turns to be 6 kilograms. Because the remaining quantity, which is 3, corresponding to the currently selected smoke grenades is less than the initial quantity, which is 5, and the remaining total weight, which is 6 kilograms, corresponding to the currently selected smoke grenades is less than the initial total weight, which is 10 kilograms, in this case, the sound effect intensity value corresponding to the currently selected smoke grenades needs to be lowered.

Second situation: If the remaining quantity corresponding to each type of object currently selected is equal to the initial quantity corresponding to each type of object currently selected, and the remaining total weight corresponding to each type of object currently selected is less than the initial total weight corresponding to each type of object currently selected, the sound effect intensity value corresponding to each type of object currently selected is lowered.

In the second situation, although the remaining quantity corresponding to each type of object currently selected is equal to the initial quantity corresponding to each type of object currently selected, as the user uses the object in the application program, each type of object currently selected is damaged, and as a result, the total weight corresponding to each type of object currently selected decreases, that is, the remaining total weight corresponding to each type of object currently selected is less than the initial total weight corresponding to each type of object currently selected, and when the total weight of each type of object currently selected decreases, the sound effect intensity value corresponding to each type of object currently selected decreases; therefore, in this case, the sound effect intensity value corresponding to each type of object currently selected needs to be lowered.

For ease of comprehension of the foregoing process, detailed description is provided in the following by using a specific example.

For example, the currently selected object is body armor with helmet; as the user uses the body armor in the application program, the body armor with helmet is damaged, and therefore, the total weight of the body armor with helmet decreases. Because the remaining total weight corresponding to each type of object currently selected is less than the initial total weight corresponding to each type of object currently selected, in this case, the sound effect corresponds to the currently selected body armor with helmet needs to be lowered

205: Detect a current implementation environment, and determine, according to the current implementation environment, combination ratios for combining the sound effects corresponding to all the types of objects.

The implementation environment includes, but is not limited to, the stiffness of a ground surface material. Because in different implementation environments, all objects in a same state in a same application correspond to different sound effect intensity values, for example, when the ground surface material is stiff, all objects in a same state in a same application correspond to large sound effect intensity values; and when the ground surface material is soft, all objects in a same state in a same application correspond to small sound effect intensity values. Therefore, in order to accurately present a change in states of objects used in the application, the method provided by this embodiment needs to detect a current implementation environment.

By using the implementation environment being the ground surface material as an example, the manner of detecting a current implementation environment includes, but is not limited to, detecting a deformation of the ground surface by using a deformation measuring apparatus, where a small deformation of the ground surface is detected when the ground surface material is stiff, and a large deformation of the ground surface is detected when the ground surface material is soft.

Further, in order to make the sound effect intensities corresponding to all types of objects in the application capable of reflecting a change in current states of all types of objects in the application in real time, after detecting the current implementation environment, the method further determines, according to the current implementation environment, combination ratios for combining the sound effects corresponding to all the types of objects.

Specifically, by using a first-person modern shooting game as an example, the determining, according to the current implementation environment, combination ratios for combining the sound effects corresponding to all the types of objects includes, but is not limited to, when the ground surface material is stiff, setting combination ratios for combining the sound effects of the primary weapon, grenade, and tactical equipment backpack to large values, and setting combination ratios for combining the sound effects of the secondary weapon, melee weapon, and body armor to small values; and when the ground surface material is soft, setting the combination ratios for combining the sound effects of the primary weapon, grenade, and tactical equipment backpack to small values, and setting the combination ratios for combining the sound effects of the secondary weapon, melee weapon, and body armor to large values.

206: Combine the sound effects corresponding to all the types of objects according to the determined combination ratios and the adjusted sound effect intensity values corresponding to all the types of objects currently selected.

Because the combination ratios for combining the sound effect intensities corresponding to all the types of objects have been determined according to the current implementation environment in step 205, in this step, on the basis of step 205, the sound effects are combined according to the determined combination ratios and the adjusted sound effect intensity values corresponding to all the types of objects currently selected, and further, the combined sound effects are used as a sound effect adjustment result.

For ease of comprehension of the foregoing process, detailed description is provided in the following by using a specific example.

For example, the currently selected objects are classified into four types, which are machine gun, half sword, flash grenade, and night vision device, where combination ratios of the machine gun, half sword, flash grenade, and night vision device are 70%, 50%, 30%, and 40%; the sound effect intensity value of the machine gun is 0.5a, the sound effect intensity value of the half sword is 0.6b, the sound effect intensity value of the flash grenade is 0.4d, and the sound effect intensity value of the night vision device is 0.9e; in this case, a sound effect intensity value obtained by combining the sound effects corresponding to all the types of objects according to the determined combination ratios and the adjusted sound effect intensity values corresponding to all the types of objects is: 0.5a*70%+0.6b*50%+0.4d*30%+0.9e*40%, that is, 0.35a+0.3b+0.12d+0.36e is used as an adjustment result.

So far, the adjustment f the sound effect is completed by using the foregoing process. To help the user hear the adjusted sound effect, the method provided by this embodiment further executes a step of playing the adjusted sound effect. The manner of playing the adjusted sound effect includes, but is not limited to, playing the sound effect by using an audio playback apparatus.

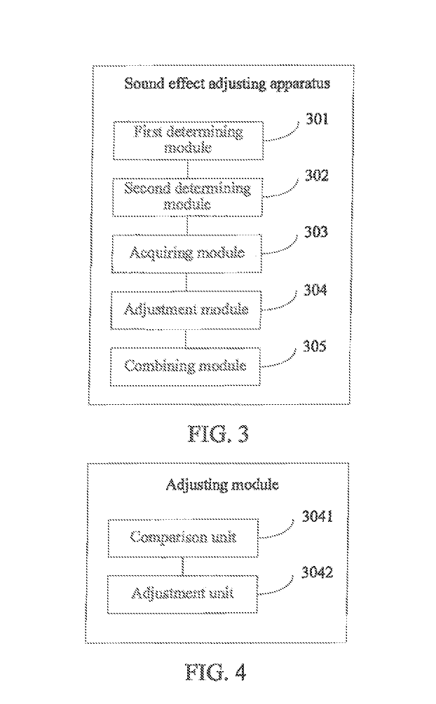

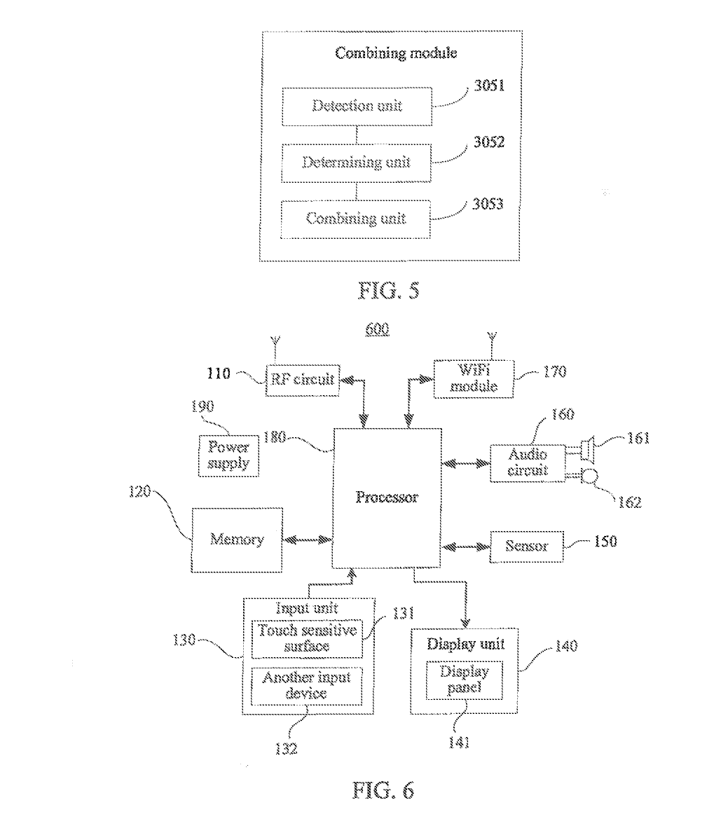

Referring to FIG. 3, this embodiment of the present invention provides a sound effect adjusting apparatus, the apparatus including:
a first determining module 301, configured to determine an initial sound effect intensity value corresponding to each object currently selected;
a second determining module 302, configured to determine, according to the initial sound effect intensity value corresponding to each object currently selected, a sound effect intensity value corresponding to each type of object currently selected, each type of object including at least one object;
an acquiring module 303, configured to acquire a state of each type of object currently selected, different states corresponding to different sound effect intensity values;
an adjustment module 304, configured to adjust, according to the state of each type of object currently selected, the sound effect intensity value corresponding to each type of object, to obtain an adjusted sound effect intensity value corresponding to each type of object; and
a combining module 305, configured to combine, according to sound effect intensity values of all types of objects currently selected, sound effects corresponding to all the types of objects, and use the combined sound effects as a sound effect adjustment result.

As a preferable embodiment, the state of each type of object currently selected includes: a remaining quantity and a remaining total weight corresponding to each type of object currently selected; and
the acquiring module 303 is configured to acquire the remaining quantity and the remaining total weight corresponding to each type of object currently selected.

Referring to FIG. 4, the adjustment module 304 includes:
a comparison unit 3041, configured to compare the remaining quantity corresponding to each type of object currently selected with an initial quantity corresponding to each type of object currently selected, and compare the remaining total weight corresponding to each type of object currently selected with an initial total weight corresponding to each type of object currently selected; and
an adjustment unit 3042, configured to adjust the sound effect intensity value corresponding to each type of object according to a comparison result.

As a preferable embodiment, the adjustment unit 3042 is configured to lower the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

Referring to FIG. 5, the combining module 305 includes:
a detection unit 3051, configured to detect a current implementation environment;
a determining unit 3052, configured to determine, according to the current implementation environment, combination ratios for combining the sound effects corresponding to all the types of objects; and
a combining unit 3053, configured to combine the sound effects corresponding to all the types of objects according to the determined combination ratios and the adjusted sound effect intensity values corresponding to all the types of objects currently selected.

In conclusion, the apparatus provided by this embodiment of the present invention can combine sound effects corresponding to all types of objects according to adjusted sound effect intensity values corresponding to all the types of objects currently selected, so that the combined sound effects can reflect a change in states of the currently selected objects, and therefore, the adjusted sound effect is time sensitive.

Referring to FIG. 6, FIG. 6 shows a schematic structural diagram of a terminal involved in the embodiments of the present invention. The terminal may be used for implementing the sound effect adjusting method provided in the foregoing embodiment. Specifically:

In this embodiment, a terminal 600 may include components such as a memory 120 having one or more computer readable storage media, an input unit 130, a display unit 140, a processor 180 having one or more processing cores, and a power supply 180. In another embodiments, the terminal 600 may further include a radio frequency (RF) circuit 110, a sensor 150, an audio circuit 160, and a Wireless Fidelity (WiFi) module 170. A person skilled in the art may understand that, the terminal structure shown in FIG. 6 does not constitute any limitation on the terminal, and components more than or fewer than those shown in the figure may be included, or some components may be combined, or a different component deployment may be used.

The RF circuit 110 may be configured to receive and send signals during an information sending and receiving process or a call process. Particularly, the RF circuit 1110 receives downlink information from a base station, then delivers the downlink information to the one or more processors 180 for processing, and sends related uplink data to the base station. Generally, the RF circuit 110 includes, but is not limited to, an antenna, at least one amplifier, a tuner, one or more oscillators, a subscriber identity module (SIM) card, a transceiver, a coupler, a low noise amplifier (LNA), and a duplexer. In addition, the RF circuit 110 may also communicate with a network and another device by means of wireless communications. The wireless communication may use any communications standard or protocol, which includes, but is not limited to, Global System for Mobile Communication (GSM), General Packet Radio Service (GPRS), Code Division Multiple Access (CDMA), Wideband Code Division Multiple Access (WCDMA), Long Term Evolution, (LTE), e-mail, and Short Messaging Service (SMS).

The memory 120 may be configured to store a software program and module. The processor 180 runs the software program and module stored in the memory 120, to implement various functional applications and data processing. The memory 120 may mainly include a program storage area and a data storage area. The program storage area may store an operating system, an application program required by at least one function (such as a sound playback function and an image display function), and the like. The data storage area may store data (such as audio data and an address book) created according to use of the terminal 600, and the like. In addition, the memory 120 may include a high-speed random access memory, and may also include a non-volatile memory, such as at least one magnetic disk storage device, a flash memory, or another volatile solid-state storage device. Accordingly, the memory 120 may further include a memory controller, so that the processor 180 and the input unit 130 access the memory 120.

The input unit 130 may be configured to receive input digit or character information, and generate a keyboard, mouse, joystick, optical, or track ball signal input related to the user setting and function control. Specifically, the input unit 130 may include a touch-sensitive surface 131 and another input device 132. The touch-sensitive surface 131, which may also be referred to as a touch screen or a touch panel, may collect a touch operation of a user on or near the touch-sensitive surface (such as an operation of a user on or near the touch-sensitive surface 131 by using any suitable object or accessory, such as a finger or a stylus), and drive a corresponding connection apparatus according to a preset program. Optionally, the touch-sensitive surface 131 may include two parts: a touch detection apparatus and a touch controller. The touch detection apparatus detects a touch position of the user, detects a signal generated by the touch operation, and transfers the signal to the touch controller. The touch controller receives the touch information from the touch detection apparatus, converts the touch information into touch point coordinates, and sends the touch point coordinates to the processor 180. Moreover, the touch controller can receive and execute a command sent from the processor 180. In addition, the touch-sensitive surface 131 may be a resistive, capacitive, infrared, or surface acoustic wave type touch-sensitive surface. In addition to the touch-sensitive surface 131, the input unit 130 may further include the another input device 132. Specifically, the another input device 132 may include, but is not limited to, one or more of a physical keyboard, a functional key (such as a volume control key or a switch key), a track ball, a mouse, and a joystick.

The display unit 140 may be configured to display information input by the user or information provided for the user, and various graphical user interfaces of the terminal. The graphical user interfaces may be formed by a graph, a text, an icon, a video, and any combination thereof. The display unit 140 may include a display panel 141. Optionally, the display panel 141 may be configured by using a liquid crystal display (LCD), an organic light-emitting diode (OLED), or the like. Further, the touch-sensitive surface 131 may cover the display panel 141. After detecting a touch operation on or near the touch-sensitive surface 131, the touch-sensitive surface 131 transfers the touch operation to the processor 180, so as to determine the type of the touch event. Then, the processor 180 provides a corresponding visual output on the display panel 141 according to the type of the touch event. Although, in FIG. 6, the touch-sensitive surface 131 and the display panel 141 are used as two separate parts to implement input and output functions, in some embodiments, the touch-sensitive surface 131 and the display panel 141 may be integrated to implement the input and output functions.

The terminal 600 may further include at least one sensor 150, such as an optical sensor, a motion sensor, and other sensors. Specifically, the optical sensor may include an ambient light sensor and a proximity sensor. The ambient light sensor may adjust luminance of the display panel 141 according to brightness of the ambient light. The proximity sensor may switch off the display panel 141 and/or backlight when the terminal 600 is moved to the ear. As one type of motion sensor, a gravity acceleration sensor may detect magnitude of accelerations in various directions (generally on three axes), may detect magnitude and a direction of the gravity when static, and may be applied to an application that recognizes the attitude of a mobile phone (for example, switching between landscape orientation and portrait orientation, a related game, and magnetometer attitude calibration), a function related to vibration recognition (such as a pedometer and a knock), and the like. Other sensors, such as a gyroscope, a barometer, a hygrometer, a thermometer, and an infrared sensor, which may be configured in the terminal 600, are not further described herein.

The audio circuit 160, a loudspeaker 161, and a microphone 162 may provide audio interfaces between the user and the terminal 600. The audio circuit 160 may convert received audio data into an electric signal and transmit the electric signal to the loudspeaker 161. The loudspeaker 161 converts the electric signal into a sound signal for output. On the other hand, the microphone 162 converts a collected sound signal into an electric signal. The audio circuit 160 receives the electric signal and converts the electric signal into audio data, and outputs the audio data to the processor 180 for processing. Then, the processor 180 sends the audio data to, for example, another terminal device by using the RF circuit 110, or outputs the audio data to the memory 120 for further processing. The audio circuit 160 may further include an earplug jack, so as to provide communication between a peripheral earphone and the terminal 600.

WiFi is a short distance wireless transmission technology. The terminal 600 may help, by using the WiFi module 170, the user to receive and send e-mails, browse web pages, access stream media, and so on, which provides wireless broadband Internet access for the user. Although FIG. 6 shows the WiFi module 170, it may be understood that the WiFi module is not a necessary component of the terminal, and when required, the WiFi module may be omitted as long as the scope of the essence of the present disclosure is not changed.

The processor 180 is the control center of the terminal 600, and is connected to various parts of the mobile phone by using various interfaces and lines. By running or executing the software program and/or module stored in the memory 120, and invoking data stored in the memory 120, the processor 180 performs various functions and data processing of the terminal memory 120, thereby performing overall monitoring on the mobile phone. Optionally, the processor 180 may include one or more processing cores. Preferably, the processor 180 may integrate an application processor and a modem processor. The application processor mainly processes an operating system, a user interface, an application programs, and the like, and the modem processor mainly processes wireless communication. It can be understood that the foregoing modem processor may not be integrated in the processor 180.

The terminal 600 may further include the power supply 190 (such as a battery) for supplying power to the components. Preferably, the power supply may be logically connected to the processor 180 through a power management system, thereby implementing functions such as charging, discharging, and power consumption management by using the power supply management system. The power supply 190 may further include any component, such as one or more direct current or alternating current power supplies, a re-charging system, a power supply fault detection circuit, a power supply converter or an inverter, and a power supply state indicator.

Although not shown in the figure, the terminal 600 may further include a camera, a Bluetooth module, and the like, which are not further described herein. Specifically, in this embodiment, the display unit of the terminal 600 is a touch screen display, and the terminal 600 further includes a memory and one or more programs. The one or more programs are stored in the memory, and are configured to be executed by one or more processors. The one or more programs include instructions for executing the following operations:
determining an initial sound effect intensity value corresponding to each object currently selected;
determining, according to the initial sound effect intensity value corresponding to each object currently selected, a sound effect intensity value corresponding to each type of object currently selected, each type of object including at least one object;
acquiring a state of each type of object currently selected, different states corresponding to different sound effect intensity values;
adjusting, according to the state of each type of object currently selected, the sound effect intensity value corresponding to each type of object, to obtain an adjusted sound effect intensity value corresponding to each type of object; and
combining, according to sound effect intensity values of all types of objects currently selected, sound effects corresponding to all the types of objects, and using the combined sound effects as a sound effect adjustment result.

Assuming that the foregoing is a first possible implementation manner, in a second possible implementation manner provided on the basis of the first possible implementation manner, the memory of the terminal further includes an instruction for executing the following operation: the state of each type of object currently selected includes a remaining quantity and a remaining total weight corresponding to each type of object currently selected; and
the acquiring a state of each type of object currently selected includes:
acquiring the remaining quantity and the remaining total weight corresponding to each type of object currently selected.

In a third possible implementation manner provided on the basis of the first possible implementation manner or the second possible implementation manner, the memory of the terminal further includes an instruction for executing the following operation:

the adjusting, according to the state of each type of object currently selected, the sound effect intensity value corresponding to each type of object includes:
comparing the remaining quantity corresponding to each type of object currently selected with an initial quantity corresponding to each type of object currently selected, and comparing the remaining total weight corresponding to each type of object currently selected with an initial total weight corresponding to each type of object currently selected; and
adjusting the sound effect intensity value corresponding to each type of object according to a comparison result.

In a fourth possible implementation manner provided on the basis of the first to third possible implementation manners, the memory of the terminal further includes an instruction for executing the following operation: the adjusting the sound effect intensity value corresponding to each type of object according to a comparison result includes:
lowering the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

In a fifth possible implementation manner provided on the basis of the first to fourth possible implementation manners, the memory of the terminal further includes an instruction for executing the following operation: the combining, according to sound effect intensity values of all types of objects currently selected, sound effects corresponding to all the types of objects includes:
detecting a current implementation environment, and determining, according to the current implementation environment, combination ratios for combining the sound effects corresponding to all the types of objects; and
combining the sound effects corresponding to all the types of objects according to the determined combination ratios and the adjusted sound effect intensity values corresponding to all the types of objects currently selected.

The terminal provided by this embodiment of the present invention determines, according to an initial sound effect intensity value corresponding to each object currently selected, a sound effect intensity value corresponding to each type of object currently selected, further adjusts the sound effect intensity value corresponding to each type of object according to a state of each type of object currently selected, and combines sound effects corresponding to all types of objects according to adjusted sound effect intensity values corresponding to all the types of objects currently selected, so that the combined sound effects can reflect a change in states of the currently selected objects, and therefore, the adjusted sound effect is time sensitive.

This embodiment of the present invention further provides a computer readable storage medium, where the computer readable storage medium may be the computer readable storage medium included in the memory in the foregoing embodiment, or a separate computer readable storage medium that is not installed in the terminal. The computer readable storage medium stores one or more programs, and the one or more programs are executed by one or more processors to implement a sound effect adjusting method, where the method includes:
determining an initial sound effect intensity value corresponding to each object currently selected;
determining, according to the initial sound effect intensity value corresponding to each object currently selected, a sound effect intensity value corresponding to each type of object currently selected, each type of object including at least one object;
acquiring a state of each type of object currently selected, different states corresponding to different sound effect intensity values;
   adjusting, according to the state of each type of object currently selected, the sound effect intensity value corresponding to each type of object, to obtain an adjusted sound effect intensity value corresponding to each type of object; and
combining, according to sound effect intensity values of all types of objects currently selected, sound effects corresponding to all the types of objects, and using the combined sound effects as a sound effect adjustment result.

Assuming that the foregoing is a first possible implementation manner, in a second possible implementation manner provided on the basis of the first possible implementation manner, the memory of the terminal further includes an instruction for executing the following operation: the state of each type of object currently selected includes a remaining quantity and a remaining total weight corresponding to each type of object currently selected; and
the acquiring a state of each type of object currently selected includes:
acquiring the remaining quantity and the remaining total weight corresponding to each type of object currently selected.

In a third possible implementation manner provided on the basis of the first possible implementation manner or the second possible implementation manner, the memory of the terminal further includes an instruction for executing the following operation:

the adjusting, according to the state of each type of object currently selected, the sound effect intensity value corresponding to each type of object includes:
comparing the remaining quantity corresponding to each type of object currently selected with an initial quantity corresponding to each type of object currently selected, and comparing the remaining total weight corresponding to each type of object currently selected with an initial total weight corresponding to each type of object currently selected; and
adjusting the sound effect intensity value corresponding to each type of object according to a comparison result.

In a fourth possible implementation manner provided on the basis of the first to third possible implementation manners, the memory of the terminal further includes an instruction for executing the following operation: the adjusting the sound effect intensity value corresponding to each type of object according to a comparison result includes:
lowering the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

In a fifth possible implementation manner provided on the basis of the first to fourth possible implementation manners, the memory of the terminal further includes an instruction for executing the following operation: the combining, according to sound effect intensity values of all types of objects currently selected, sound effects corresponding to all the types of objects includes:
detecting a current implementation environment, and determining, according to the current implementation environment, combination ratios for combining the sound effects corresponding to all the types of objects; and
combining the sound effects corresponding to all the types of objects according to the determined combination ratios and the adjusted sound effect intensity values corresponding to all the types of objects currently selected.

The computer readable storage medium provided by this embodiment of the present invention determines, according to an initial sound effect intensity value corresponding to each object currently selected, a sound effect intensity value corresponding to each type of object currently selected, further adjusts the sound effect intensity value corresponding to each type of object according to a state of each type of object currently selected, and combines sound effects corresponding to all types of objects according to adjusted sound effect intensity values corresponding to all the types of objects currently selected, so that the combined sound effects can reflect a change in states of the currently selected objects, and therefore, the adjusted sound effect is time sensitive.

It should be noted that, when the sound effect adjusting apparatus provided in the foregoing embodiment adjusts a sound effect, the foregoing division of functional modules is merely an example for description, and in an actual application, the foregoing functions may be completed by different functional modules as required. In other words, the internal structure of the sound effect adjusting apparatus is divided into different functional modules, so as to complete all or some of functions described above. In addition, the sound effect adjusting apparatus provided in the foregoing embodiment belongs to a same conception as the embodiment of the sound effect adjusting method; for a specific implementation process, refer to the method embodiment, and details are not described herein again.

The sequence numbers of the foregoing embodiments of the present invention are merely for the convenience of description, and do not imply the preference among the embodiments.

A person of ordinary skill in the art may understand that all or some of the steps of the foregoing embodiments may be implemented by using hardware, or may be implemented by a program instructing relevant hardware. The program may be stored in a computer readable storage medium. The storage medium may be a read-only memory, a magnetic disk, an optical disc, or the like.

The foregoing descriptions are merely preferred embodiments of the present invention, but are not intended to limit the present invention. Any modification, equivalent replacement, or improvement made within the spirit and principle of the present invention shall fall within the protection scope of the present invention.

What is claimed is:

1. A sound effect adjusting method, applied to a terminal, the terminal comprising one or more processors, a memory, and program instructions stored in the memory, the program instructions being executed by the one or more processors, the method comprising:
determining an initial sound effect intensity value corresponding to each object currently selected;
determining, according to the initial sound effect intensity value corresponding to each object currently selected, a sound effect intensity value corresponding to each type of object currently selected, each type of object comprising at least one object;
acquiring a state of each type of object currently selected, different states corresponding to different sound effect intensity values;
adjusting, according to the state of each type of object currently selected, the sound effect intensity value corresponding to each type of object, to obtain an adjusted sound effect intensity value corresponding to each type of object; and
combining, according to sound effect intensity values of all types of objects currently selected, sound effects corresponding to all the types of objects, and using the combined sound effects as a sound effect adjustment result.

2. The method according to claim 1, wherein the state of each type of object currently selected comprises:
a remaining quantity and a remaining total weight corresponding to each type of object currently selected; and
the acquiring a state of each type of object currently selected comprises:
acquiring the remaining quantity and remaining total weight corresponding to each type of object currently selected.

3. The method according to claim 1, wherein the adjusting, according to the state of each type of object currently selected, the sound effect intensity value corresponding to each type of object comprises:
comparing a remaining quantity corresponding to each type of object currently selected with an initial quantity corresponding to each type of object currently selected, and comparing a remaining total weight corresponding to each type of object currently selected with an initial total weight corresponding to each type of object currently selected; and
adjusting the sound effect intensity value corresponding to each type of object according to a comparison result.

4. The method according to claim 3, wherein the adjusting the sound effect intensity value corresponding to each type of object according to a comparison result comprises:
lowering the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

5. The method according to claim 1, wherein the combining, according to sound effect intensity values of all types of objects currently selected, sound effects corresponding to all the types of objects, comprises:
detecting a current implementation environment, and determining, according to the current implementation environment, combination ratios for combining the sound effects corresponding to all the types of objects; and
combining the sound effects corresponding to all the types of objects according to the determined combination ratios and the adjusted sound effect intensity values corresponding to all the types of objects currently selected.

6. A sound effect adjusting apparatus, comprising:
one or more processors;
a memory; and
one or more program modules, stored in the memory, and executed by the one or more processors, the one or more program modules comprising:
a first determining module, configured to determine an initial sound effect intensity value corresponding to each object currently selected;
a second determining module, configured to determine, according to the initial sound effect intensity value corresponding to each object currently selected, a sound effect intensity value corresponding to each type of object currently selected, each type of object comprising at least one object;
an acquiring module, configured to acquire a state of each type of object currently selected, different states corresponding to different sound effect intensity values;
an adjustment module, configured to adjust, according to the state of each type of object currently selected, the sound effect intensity value corresponding to each type of object, to obtain an adjusted sound effect intensity value corresponding to each type of object; and
a combining module, configured to combine, according to sound effect intensity values of all types of objects currently selected, sound effects corresponding to all the types of objects, and use the combined sound effects as a sound effect adjustment result.

7. The apparatus according to claim 6, wherein the state of each type of object currently selected comprises: a remaining quantity and a remaining total weight corresponding to each type of object currently selected;
the acquiring module is configured to acquire the remaining quantity and remaining total weight corresponding to each type of object currently selected.

8. The apparatus according to claim 6, wherein the adjustment module comprises:
a comparison unit, configured to compare a remaining quantity corresponding to each type of object currently selected with an initial quantity corresponding to each type of object currently selected, and compare a remaining total weight corresponding to each type of object currently selected with an initial total weight corresponding to each type of object currently selected; and
an adjustment unit, configured to adjust the sound effect intensity value corresponding to each type of object according to a comparison result.

9. The apparatus according to claim 8, wherein the adjustment unit is configured to lower the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

10. The apparatus according to claim 6, wherein the combining module comprises:
a detection unit, configured to detect a current implementation environment;
a determining unit, configured to determine, according to the current implementation environment, combination ratios for combining the sound effects corresponding to all the types of objects; and
a combining unit, configured to combine the sound effects corresponding to all the types of objects according to the determined combination ratios and the adjusted sound effect intensity values corresponding to all the types of objects currently selected.

11. A non-transitory computer readable storage medium, having computer executable instructions stored thereon, and executing a sound effect adjusting method when these executable instructions are run on a terminal, the method comprising:
determining an initial sound effect intensity value corresponding to each object currently selected;
determining, according to the initial sound effect intensity value corresponding to each object currently selected, a sound effect intensity value corresponding to each type of object currently selected, each type of object comprising at least one object;
acquiring a state of each type of object currently selected, different states corresponding to different sound effect intensity values;
adjusting, according to the state of each type of object currently selected, the sound effect intensity value corresponding to each type of object, to obtain an adjusted sound effect intensity value corresponding to each type of object; and
combining, according to sound effect intensity values of all types of objects currently selected, sound effects corresponding to all the types of objects, and using the combined sound effects as a sound effect adjustment result.

12. The non-transitory computer readable storage medium according to claim 11, wherein the state of each type of object currently selected comprises:
a remaining quantity and a remaining total weight corresponding to each type of object currently selected; and
the acquiring a state of each type of object currently selected comprises:
acquiring the remaining quantity and remaining total weight corresponding to each type of object currently selected.

13. The non-transitory computer readable storage medium according to claim 11, wherein the adjusting, according to the state of each type of object currently selected, the sound effect intensity value corresponding to each type of object comprises:
comparing a remaining quantity corresponding to each type of object currently selected with an initial quantity corresponding to each type of object currently selected, and comparing a remaining total weight corresponding to each type of object currently selected with an initial total weight corresponding to each type of object currently selected; and
adjusting the sound effect intensity value corresponding to each type of object according to a comparison result.

14. The non-transitory computer readable storage medium according to claim 13, wherein the adjusting the sound effect intensity value corresponding to each type of object according to a comparison result comprises:
lowering the sound effect intensity value corresponding to each type of object currently selected if the remaining quantity corresponding to each type of object currently selected is not greater than the initial quantity corresponding to each type of object currently selected and the remaining total weight corresponding to each type of object currently selected is less than the initial total weight corresponding to each type of object currently selected.

15. The non-transitory computer readable storage medium according to claim 11, wherein the combining, according to sound effect intensity values of all types of objects currently selected, sound effects corresponding to all the types of objects, comprises:
detecting a current implementation environment, and determining, according to the current implementation environment, combination ratios for combining the sound effects corresponding to all the types of objects; and
combining the sound effects corresponding to all the types of objects according to the determined combination ratios and the adjusted sound effect intensity values corresponding to all the types of objects currently selected.
